(19) United States
(12) Patent Application Publication
(10) Pub. No.: US 2026/0344066 A1
(43) Pub. Date: Oct. 29, 2026

(54) RESISTANCE TESTING STRUCTURES

(71) Applicant: GlobalFoundries U.S. Inc., Malta, NY (US)

(72) Inventors: Yusheng Bian, Ballston Lake, NY (US); Won Suk Lee, Malta, NY (US); Mrunal Shah, Clifton Park, NY (US); Abdelsalam Aboketaf, Essex Junction, VT (US); Xiaoxiao Zhang, Ballston Lake, NY (US); Kevin K. Dezfulian, Arlington, VA (US); Felix Beaudoin, Halfmoon, NY (US); Arman Najafi, Albany, NY (US)

(21) Appl. No.: 19/190,062

(22) Filed: Apr. 25, 2025

(51) Int. Cl. H10F 30/223; H10F 71/00; H10F 77/14

(52) U.S. Cl. CPC H10F 30/223; H10F 71/00; H10F 77/147

(57) ABSTRACT

Photonic structures that include a resistor and methods of forming such photonic structures. The photonic structure comprises a dielectric layer and a resistor that includes a semiconductor layer. The semiconductor layer includes a first doped region, a second doped region, a recess, and a portion of the dielectric layer inside the recess. A first contact extends through the dielectric layer to the first doped region, and a second contact extends through the dielectric layer to the second doped region.

### BACKGROUND

The disclosure relates to photonics chips and, more specifically, to photonic structures that include a resistor and methods of forming such photonic structures.

Photodetectors in photonic chips find use in many applications and systems including, but not limited to, data communication systems and data computation systems. A photonic chip includes a photonic integrated circuit consisting of photonic components, such as modulators, polarizers, and optical couplers, that are used to manipulate light received from a light source, such as an optical fiber or a laser.

A photodetector may be employed in the photonic integrated circuit to convert light, which may be modulated as an optical signal, into an electrical signal. Testing structures may be used to determine performance parameters for a photodetector. However, conventional testing structures be unable to provide accurate determinations of photodetector performance parameters.

Improved photonic structures that include a resistor and methods of forming such photonic structures are needed.

### SUMMARY

In an embodiment of the invention, a photonic structure comprises a dielectric layer and a resistor including a semiconductor layer. The semiconductor layer includes a first doped region, a second doped region, a recess, and a portion of the dielectric layer inside the recess. The semiconductor layer has a first thickness inside the recess and a second thickness outside the recess, and the second thickness is greater than the first thickness. A first contact extends through the dielectric layer to the first doped region, and a second contact extends through the dielectric layer to the second doped region.

In an embodiment of the invention, a photonic structure comprises a resistor including a semiconductor layer. The semiconductor layer includes a first doped region, a second doped region adjacent to the first doped region, a germanium layer on a portion of the semiconductor layer, and a recess laterally between the first doped region and the germanium layer. The semiconductor layer has a first thickness inside the recess and a second thickness outside the recess, and the second thickness is greater than the first thickness. A first contact is coupled to the first doped region, and a second contact is coupled to the germanium layer.

In an embodiment of the invention, a photonic structure comprises a resistor including a semiconductor layer. The semiconductor layer includes a first doped region and a second doped region. A first contact is coupled to the first doped region, and a second contact is coupled to the second doped region.

In an embodiment of the invention, a method of forming a photonic structure is provided. The method comprises forming a resistor including a semiconductor layer. The semiconductor layer includes a first doped region, a second doped region, a recess, and a portion of a dielectric layer inside the recess. The semiconductor layer has a first thickness inside the recess and a second thickness outside the recess, and the second thickness is greater than the first thickness. The method further comprises forming a first contact extending through the dielectric layer to the first doped region and forming a second contact extending through the dielectric layer to the second doped region.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a top view of a structure at an initial fabrication stage of a processing method in accordance with embodiments of the invention.

FIG. 1A is a cross-sectional view taken generally along line 1A-1A in FIG. 1.

FIG. 1B is a cross-sectional view of a structure in accordance with alternative embodiments of the invention.

FIG. 2 is a cross-sectional view of the structure at a fabrication stage subsequent to FIGS. 1, 1A.

FIG. 3 is a cross-sectional view of a structure in accordance with alternative embodiments of the invention.

FIG. 4 is a cross-sectional view of a structure in accordance with alternative embodiments of the invention.

FIG. 5 is a cross-sectional view of a structure in accordance with alternative embodiments of the invention.

FIGS. 6A, 6B are cross-sectional views of a structure in accordance with alternative embodiments of the invention.

FIG. 7 is a cross-sectional view of a structure in accordance with alternative embodiments of the invention.

FIG. 8 is a cross-sectional view of a structure in accordance with alternative embodiments of the invention.

FIG. 9 is a cross-sectional view of a structure in accordance with alternative embodiments of the invention.

### DETAILED DESCRIPTION

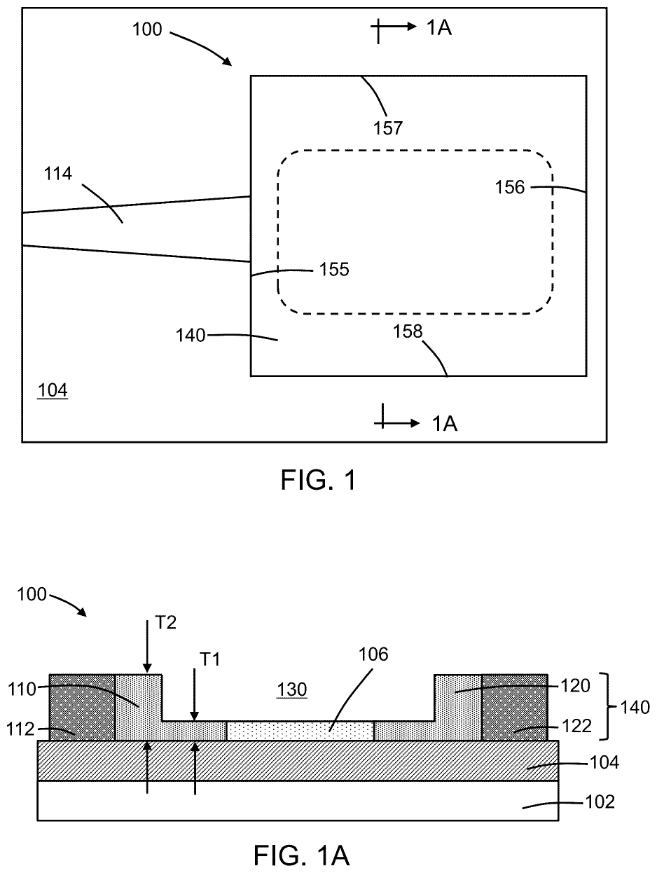

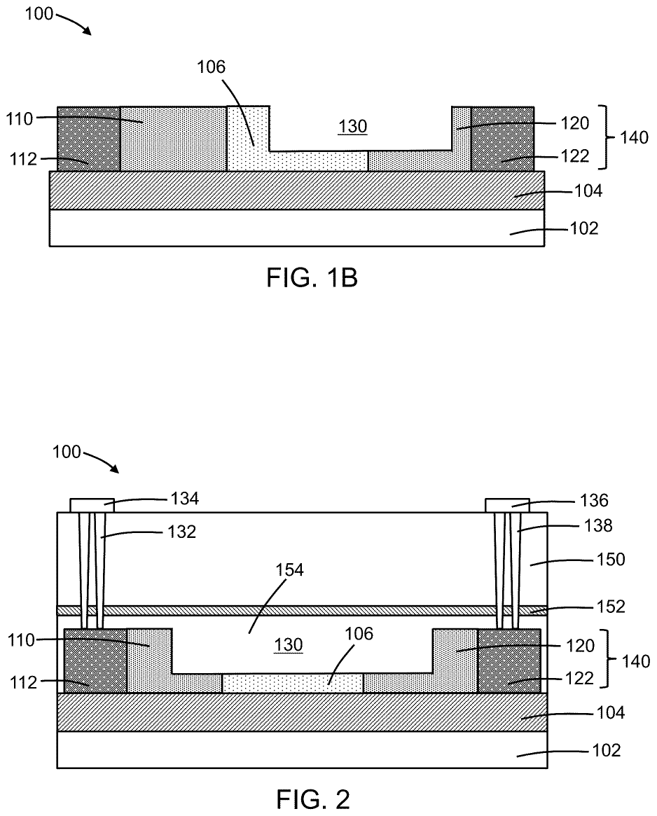

With reference to FIGS. 1, 1A and in accordance with embodiments of the invention, a photonic structure 100 is positioned on, and overlies, a semiconductor substrate 102 and a dielectric layer 104. The dielectric layer 104 is disposed on the semiconductor substrate 102. In an embodiment, the dielectric layer 104 may be comprised of a dielectric material, such as an oxide of silicon (e.g., silicon dioxide), and the semiconductor substrate 102 may be comprised of a semiconductor material, such as single-crystal silicon. In an embodiment, the dielectric layer 104 may be a buried oxide layer of a silicon-on-insulator substrate, and the dielectric layer 104 may provide low-index cladding.

In an embodiment, the photonic structure 100 may include a semiconductor layer 140 and a waveguide core 114 coupled to the semiconductor layer 140. The semiconductor layer 140 has a side edge 155, a side edge 156 opposite from the side edge 155, a side edge 157, and a side edge 158 opposite from the side edge 157. In an embodiment, the side edges 155, 156, 157, 158 may surround an outer perimeter of the semiconductor layer 140, and the side edges 155, 156, 157, 158 may extend from a top surface of the semiconductor layer 140 to a top surface of the dielectric layer 104.

In an embodiment, the waveguide core 114 and the semiconductor layer 140 may be comprised of a material having a refractive index that is greater than the refractive index of silicon dioxide. In an embodiment, the waveguide core 114 and the semiconductor layer 140 may be comprised of a semiconductor material. In an embodiment, the waveguide core 114 and the semiconductor layer 140 may be comprised of single-crystal silicon. The waveguide core 114 and the semiconductor layer 140 may be formed by patterning a layer comprised of their constituent material with lithography and etching processes. In an embodiment, the waveguide core 114 and the semiconductor layer 140 may be formed by patterning the semiconductor material, such as single-crystal silicon, of a device layer of a silicon-on-insulator substrate.

The photonic structure 100 may include an undoped region 106, a doped region 110 that is formed between the side edge 157 of the semiconductor layer 140 and undoped region 106, and a doped region 120 that is formed between the side edge 158 of the semiconductor layer 140 and the undoped region 106. The doped regions 110, 120 may extend fully through the entire thickness of the semiconductor layer 140 to the underlying dielectric layer 104. In an embodiment, the doped region 110 may differ in conductivity type from the doped region 120. In an embodiment, the doped region 110 may have p-type electrical conductivity, and the doped region 120 may have n-type electrical conductivity.

The doped region 110 may be formed by, for example, ion implantation with an implantation mask having an opening that determines the implanted area of the semiconductor layer 140. The implantation mask may include a layer of photoresist applied by a spin-coating process, pre-baked, exposed to light projected through a photomask, baked after exposure, and developed with a chemical developer to define the opening over the area of the semiconductor layer 140 to be implanted. The implantation conditions, such as ion species, dose, and kinetic energy, may be selected to tune the electrical and physical characteristics of the doped region 110. In an embodiment, the doped region 110 may be formed using multiple implantation steps, such as a deep implant and a shallow implant. The implantation mask may be stripped after forming the doped region 110. In an embodiment, the semiconductor material of the doped region 110 may contain a p-type dopant, such as boron, that provides p-type electrical conductivity.

The doped region 120 may be formed by, for example, ion implantation with an implantation mask having an opening that determines an implanted area of the semiconductor layer 140. The implantation mask may include a layer of photoresist applied by a spin-coating process, pre-baked, exposed to light projected through a photomask, baked after exposure, and developed with a chemical developer to define the opening over the area of the semiconductor layer 140 to be implanted. The implantation conditions, such as ion species, dose, and kinetic energy, may be selected to tune the electrical and physical characteristics of the doped region 120. In an embodiment, the doped region 120 may be formed using multiple implantation steps, such as a deep implant and a shallow implant. The implantation mask may be stripped after forming the doped region 120. In an embodiment, the semiconductor material of the doped region 120 may contain an n-type dopant, such as phosphorus or arsenic, that provides n-type electrical conductivity.

The undoped region 106 is laterally positioned in the semiconductor layer 140 between the doped region 110 and the doped region 120. The undoped region 106 may be comprised of intrinsic semiconductor material, such as intrinsic silicon, that is not doped by the ion implantation forming the doped region 110 and the ion implantation forming the doped region 120.

A heavily-doped region 112 may be formed by a masked ion implantation in a portion of the doped region 110 and a heavily-doped region 122 may be formed by a masked ion implantation in a portion of the doped region 120. The heavily-doped region 112 may have the same conductivity type as the doped region 110 but at a higher dopant concentration. The heavily-doped region 122 may have the same conductivity type as the doped region 120 but at a higher dopant concentration.

In an embodiment, the photonic structure 100 may include a recess 130 that extends into the undoped region 106, a portion of the doped region 110 adjacent to the undoped region 106, and a portion of the doped region 120 adjacent to the undoped region 106. The semiconductor layer 140 has a thickness T1 inside the recess 130 and a thickness T2 outside of the recess 130. The thickness T2 is greater than the thickness T1. In an embodiment, the recess 130 may be symmetrically positioned with respect to the side edges 157, 158.

The recess 130 may be patterned in the semiconductor layer 140 by lithography and etching processes. To that end, an etch mask may be formed by a lithography process over the semiconductor layer 140. The etch mask may include a layer of photoresist applied by a spin-coating process, pre-baked, exposed to light projected through a photomask, baked after exposure, and developed with a chemical developer to define an opening in the photoresist at the location for the recess 130. An etching process may be used to form the recess 130 at the location of the opening in the photoresist. The etch mask may be stripped by, for example, ashing after forming the recess 130.

With reference to FIG. 1B and in an alternative embodiment, the recess 130 may be asymmetrically positioned with respect to the side edges 157, 158. In an alternative embodiment, the photonic structure 100 may have a vertical arrangement, instead of a lateral arrangement, with the recess 130.

With reference to FIG. 2 in which like reference numerals refer to like features in FIGS. 1, 1A and at a subsequent fabrication stage, the photonic structure 100 may include dielectric layers 150, 152, 154 that are positioned on, and overlie, the semiconductor layer 140. In an embodiment, the dielectric layer 152 is positioned between the dielectric layer 150 and the dielectric layer 154. In an embodiment, the dielectric layer 150 and the dielectric layer 154 may be comprised of a dielectric material, such as an oxide of silicon (e.g., silicon dioxide), and the dielectric layer 152 may be comprised of a different dielectric material, such as silicon nitride.

The dielectric layer 154 may include a portion that is arranged inside the recess 130 such that the recess 130 is filled by dielectric material. In an embodiment, the portion of the dielectric layer 154 may fully fill the recess 130.

Contacts 132 may be formed that penetrate fully through the dielectric layers 150, 152, 154 to land on the heavily-doped region 112. Contacts 138 may be formed that penetrate fully through the dielectric layers 150, 152, 154 to land on the heavily-doped region 122. The heavily-doped region 112 electrically couples the contacts 132 to the doped region 110. The heavily-doped region 122 electrically couples the contacts 138 to the doped region 120. The contacts 132, 138 may be comprised of a metal, such as tungsten. The semiconductor layer 140 may be biased through the contacts 132, 138, which may be coupled to interconnects 134, 136, respectively, formed as metallization in an interlayer dielectric layer (not shown) over the dielectric layers 150, 152, 154.

The photonic structure 100 incorporates a resistor that includes the semiconductor layer 140, the recess 130, and the portion of the dielectric layer 154 inside the recess 130. The photonic structure 100 may be used as a testing structure to determine resistance values of subcomponents of a photodetector and isolate key physical contributing factors, such the interaction between the doped regions 110, 120 and the recess 130 and lateral diffusion. The testing may involve applying a voltage to the resistor and measuring the current to determine series resistance. Alternatively, the testing may involve applying a current to the resistor and measuring the voltage to determine series resistance. The testing may involve a four-point Kelvin measurement. The testing results may be used to deconvolve and extract photodetector subcomponent resistances and establish performance-parameter correlations for the photodetector.

The photonic structure 100, in the various embodiments disclosed herein, may provide a comprehensive suite of testing structures for deconvoluting series resistance contribution factors and isolating physical mechanisms for the total resistance. The photonic structure 100, in the various embodiments disclosed herein, may enable the correlation of photodetector figures of merit.

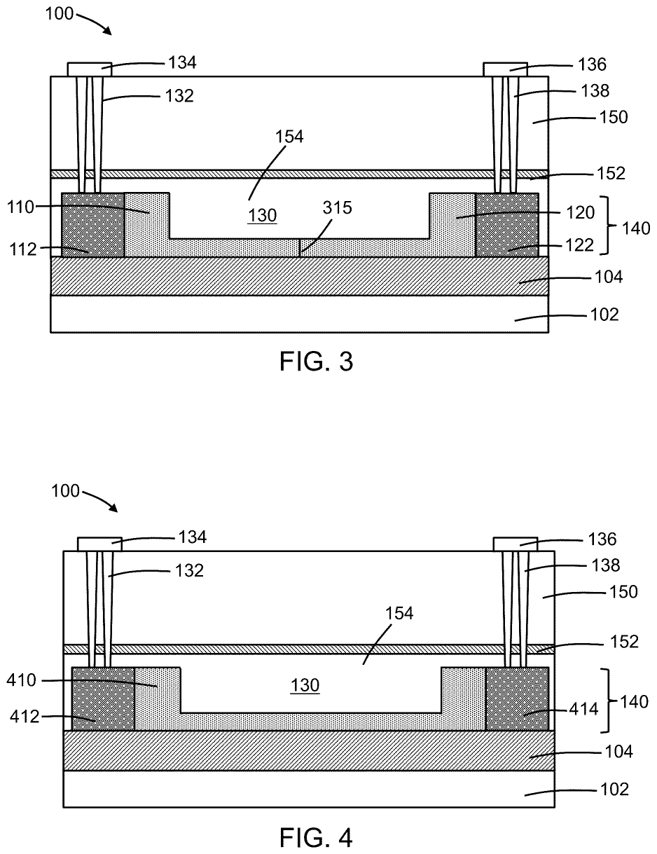

With reference to FIG. 3 and in accordance with alternative embodiments, the doped region 110 and the doped region 120 may adjoin along a P-N junction 315, and the undoped region 106 may be omitted. In an embodiment, the P-N junction 315 may be located near, or substantially near, the middle of the semiconductor layer 140. The recess 130 may penetrate into a portion of the doped region 110 and a portion of the doped region 120, and may overlap with the P-N junction 315. In an embodiment, the recess 130 may be symmetrically positioned relative to the side edges 157, 158 of the semiconductor layer 140. In an alternative embodiment, the recess 130 may be asymmetrically positioned relative to the side edges 157, 158 of the semiconductor layer 140. A portion of the dielectric layer 154 may be arranged inside the recess 130 such that the recess 130 is filled by dielectric material. In an embodiment, the recess 130 may be fully filled by the portion of the dielectric layer 154.

With reference to FIG. 4 and in accordance with alternative embodiments, the semiconductor layer 140 of the photonic structure 100 may include a doped region 410, a heavily-doped region 412, and a heavily-doped region 414 that have the same conductivity type. In an embodiment, the doped region 410 and the heavily-doped regions 412, 414 may have n-type conductivity. In an alternative embodiment, the doped region 410 and the heavily-doped regions 412, 414 may have p-type conductivity. The recess 130 is positioned inside the doped region 410, the contacts 132 land on the heavily-doped region 412, and the contacts 138 land on the heavily-doped region 414. A portion of the dielectric layer 154 may be arranged inside the recess 130 such that the recess 130 is filled by dielectric material. In an embodiment, the recess 130 may be fully filled by the portion of the dielectric layer 154.

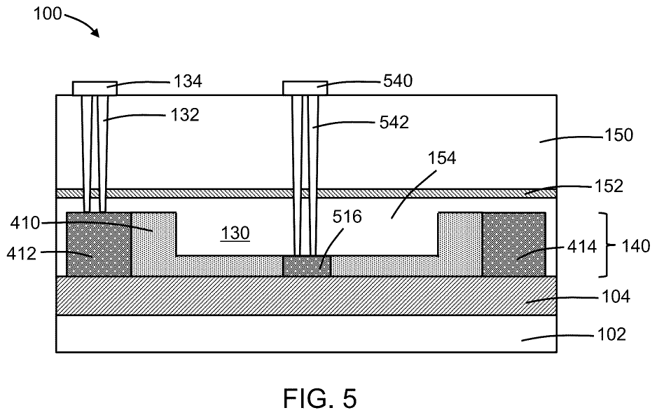

With reference to FIG. 5 and in accordance with alternative embodiments, the photonic structure 100 may include a heavily-doped region 516 positioned inside the recess 130 within the doped region 410. In an embodiment, the heavily-doped region 516 may have the same conductivity type as the doped region 410 and heavily-doped regions 412, 414. A portion of the doped region 410 is arranged between the heavily-doped region 412 and the heavily-doped region 516. A portion of the dielectric layer 154 may be arranged inside the recess 130 such that the recess 130 is filled by dielectric material. In an embodiment, the recess 130 may be fully filled by the portion of the dielectric layer 154.

Contacts 542 may be formed that penetrate fully through the dielectric layers 150, 152, 154 to land on the heavily-doped region 516. The portion of the doped region 410 between the contacts 132 and the contacts 542 may be biased through the contacts 132, 542, which may be coupled to interconnects 134, 540, respectively, formed as metallization in an interlayer dielectric layer (not shown) over the dielectric layers 150, 152, 154.

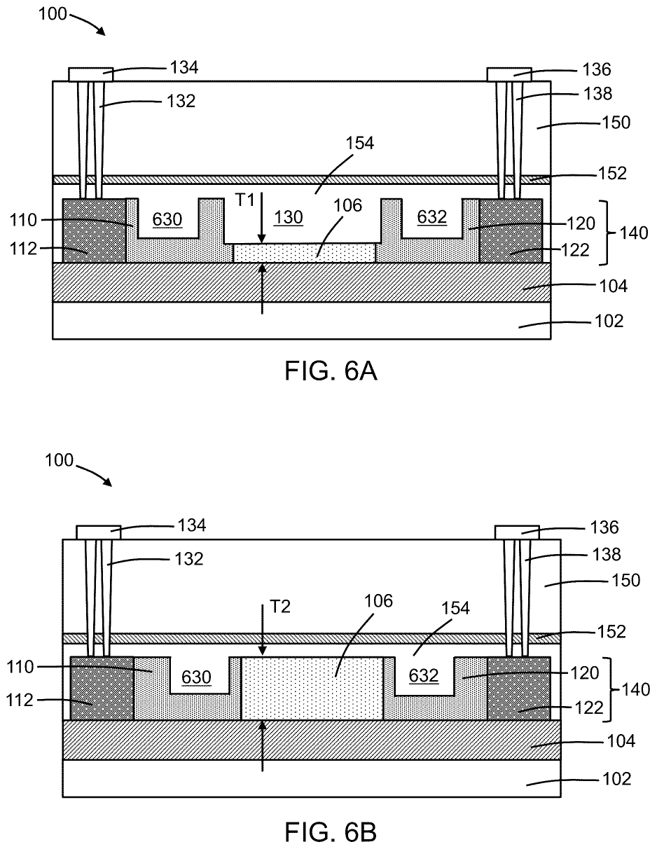

With reference to FIG. 6A and in accordance with alternative embodiments, the photonic structure 100 may include a recess 630 and a recess 632 in addition to the recess 130. The recess 130 is laterally arranged in the semiconductor layer 140 between the recess 630 and the recess 632. The recess 630 may be arranged inside the doped region 110, and the recess 632 may be arranged inside the doped region 120. In an embodiment, the recess 630 may be fully arranged inside the doped region 110, and the recess 632 may be fully arranged inside the doped region 120. Respective portions of the dielectric material of the dielectric layer 154 may fill the recess 130, the recess 630, and the recess 632. In an embodiment, the recess 130, the recess 603, and the recess 632 may be fully filled by portions of the dielectric layer 154. The photonic structure 100 incorporates a resistor that includes the semiconductor layer 140, the recess 130 and the portion of the dielectric material of the dielectric layer 154 inside the recess 130, the recess 630 and the portion of the dielectric material of the dielectric layer 154 inside the recess 630, and the recess 632 and the portion of the dielectric material of the dielectric layer 154 inside the recess 632. The semiconductor layer 140 may have the thickness T1 inside the recesses 630, 632.

With reference to FIG. 6B and in accordance with alternative embodiments, the photonic structure 100 may only include the recess 630 in the doped region 110 and the recess 632 in the doped region 120. Respective portions of the dielectric material of the dielectric layer 154 may fill the recess 630 and the recess 632. In an embodiment, the recess 603, and the recess 632 may be fully filled by portions of the dielectric layer 154. The undoped region 106 may have the thickness T2.

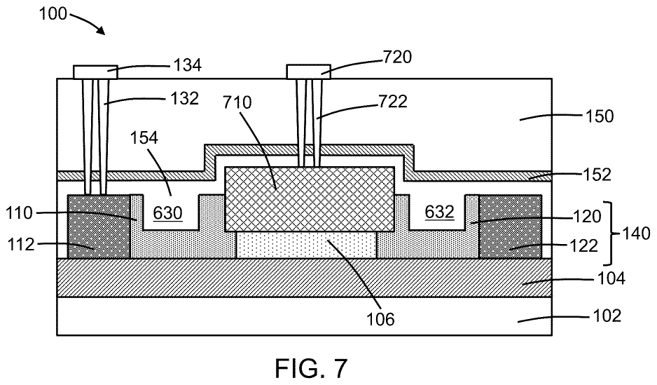

With reference to FIG. 7 and in accordance with alternative embodiments, the photonic structure 100 may include a germanium layer 710 inside the recess 130 and may omit the contacts 138 and interconnect 136. The germanium layer 710 is laterally positioned between the recess 630 and the recess 632. Contacts 722 may be formed that penetrate fully through the dielectric layers 150, 152, 154 to land on the germanium layer 710. The contacts 722 may be coupled to interconnect 720 that is formed as metallization in an interlayer dielectric layer (not shown) over the dielectric layers 150, 152, 154. In an alternative embodiment, the contacts 138 may couple the interconnect 136 with the heavily-doped region 122 and the contacts 132 and the interconnect 134 may be omitted. The photonic structure 100 may be utilized for total series resistance extraction.

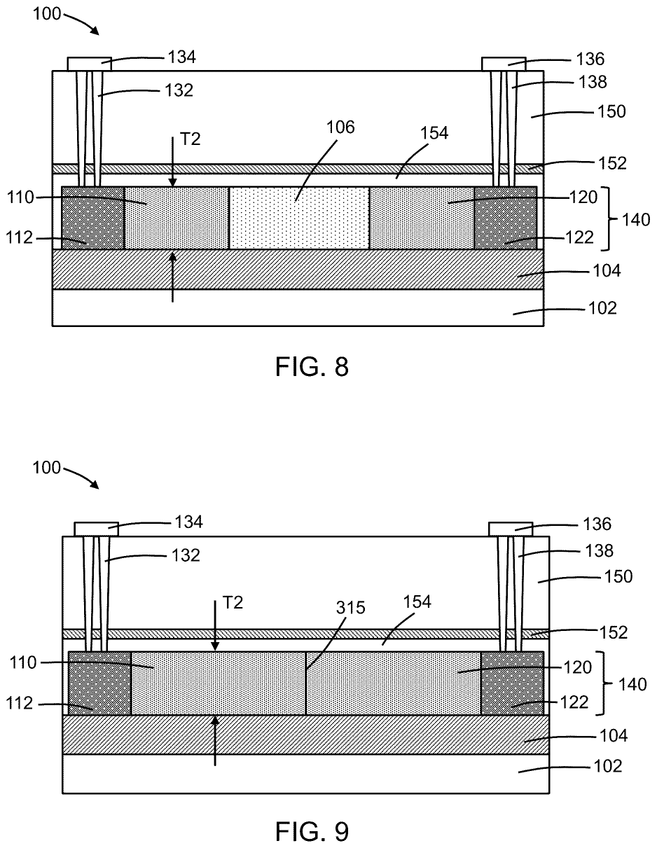

With reference to FIG. 8 and in accordance with alternative embodiments, the photonic structure 100 may include the undoped region 106, the doped region 110, and the doped region 120, but may lack the recess 130 in the semiconductor layer 140. The entire semiconductor layer 140 may have the thickness T2. The semiconductor layer 140 may function as the resistor of the testing structure.

With reference to FIG. 9 and in accordance with alternative embodiments, the photonic structure 100 may include the doped region 110, the doped region 120, and the p-n junction 315 but may lack the recess 130 in the semiconductor layer 140. The entire semiconductor layer 140 may have the thickness T2. The semiconductor layer 140 may function as the resistor of the testing structure.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/−10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. A feature may “overlie” another feature if the feature is positioned in elevation over another feature. Different features may “overlap” if a feature extends over, and covers all or a part of, another feature. A feature may “underlie” another feature if the feature is positioned in elevation below another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A photonic structure comprising:
a first dielectric layer;
a resistor including a semiconductor layer, the semiconductor layer including a first doped region, a second doped region, a first recess, and a portion of the first dielectric layer inside the first recess, the semiconductor layer having a first thickness inside the first recess and a second thickness outside the first recess, and the second thickness greater than the first thickness;
a first contact extending through the first dielectric layer to the first doped region; and
a second contact extending through the first dielectric layer to the second doped region.

2. The photonic structure of claim 1 wherein the semiconductor layer includes an intrinsic region laterally arranged between the first doped region and the second doped region, and the first recess extends into the intrinsic region.

3. The photonic structure of claim 2 wherein the semiconductor layer includes a second recess.

4. The photonic structure of claim 3 wherein the second recess extends into the first doped region.

5. The photonic structure of claim 4 wherein the semiconductor layer includes a third recess, and the third recess extends into the second doped region.

6. The photonic structure of claim 1 wherein the semiconductor layer includes a third doped region, the third doped region is laterally arranged between the first doped region and the second doped region, and the first recess extends into the third doped region.

7. The photonic structure of claim 6 wherein the first doped region and the second doped region contain a first concentration of a dopant, the third doped region contains a second concentration of the dopant, and the first concentration is greater than the second concentration.

8. The photonic structure of claim 7 wherein the dopant is a p-type dopant.

9. The photonic structure of claim 7 wherein the dopant is an n-type dopant.

10. The photonic structure of claim 7 wherein the third doped region is arranged in the semiconductor layer inside of the first recess.

11. The photonic structure of claim 7 wherein the third doped region is arranged in the semiconductor layer outside of the first recess.

12. The photonic structure of claim 1 wherein the semiconductor layer includes a second recess.

13. The photonic structure of claim 12 wherein the semiconductor layer has the first thickness inside the second recess.

14. The photonic structure of claim 12 wherein the first recess extends into the first doped region, and the second recess extends into the second doped region.

15. The photonic structure of claim 1 further comprising:
a semiconductor substrate; and
a second dielectric layer arranged between the semiconductor substrate and the resistor.

16. A photonic structure comprising:
a resistor including a semiconductor layer, the semiconductor layer including a first doped region, a second doped region adjacent to the first doped region, a germanium layer on a portion of the semiconductor layer, and a recess laterally between the first doped region and the germanium layer, the semiconductor layer having a first thickness inside the recess and a second thickness outside the recess, and the second thickness greater than the first thickness;
a first contact coupled to the first doped region; and
a second contact coupled to the germanium layer.

17. The photonic structure of claim 16 wherein the first doped region contains a first concentration of a dopant, the second doped region contains a second concentration of the dopant, and the first concentration is greater than the second concentration.

18. The photonic structure of claim 16 wherein the recess extends into the second doped region.

19. A method of forming a photonic structure, the method comprising:
forming a resistor including a semiconductor layer, wherein the semiconductor layer includes a first doped region, a second doped region, a first recess, and a portion of a dielectric layer inside the first recess, the semiconductor layer having a first thickness inside the first recess and a second thickness outside the first recess, and the second thickness greater than the first thickness;
forming a first contact extending through the dielectric layer to the first doped region; and
forming a second contact extending through the dielectric layer to the second doped region.

20. The method of claim 19 wherein the semiconductor layer includes an intrinsic region laterally arranged between the first doped region and the second doped region, the first recess extends into the intrinsic region, and the semiconductor layer includes a second recess that extends into the first doped region.
